(19) United States
(12) Patent Application Publication
(10) Pub. No.: US 2007/0235733 A1
(43) Pub. Date: Oct. 11, 2007

(54) TRANSISTOR, PIXEL ELECTRODE SUBSTRATE, ELECTRO-OPTIC DEVICE, ELECTRONIC APPARATUS, AND PROCESS FOR MANUFACTURING SEMICONDUCTOR ELEMENT

(75) Inventor: Soichi MORIYA, Chino (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 11/693,138

(22) Filed: Mar. 29, 2007

(30) Foreign Application Priority Data
Apr. 6, 2006 (JP) 2006-105582

(51) Int. Cl. H01L 31/00

(52) U.S. Cl. 257/57

(57) ABSTRACT

A transistor includes a first gate electrode, a second gate electrode formed over the first gate electrode, a source electrode formed above the first gate electrode, a drain electrode formed above the first gate electrode, and a semiconductor layer covering at least part of the source electrode and at least part of the drain electrode and disposed between the first gate electrode and the second gate electrode. The source electrode includes a first main portion extending in a direction and at least one first protrusion protruding in a direction intersecting the direction in which the first main portion extends. The drain electrode includes at least one second protrusion protruding toward the first main portion.

### BACKGROUND

1. Technical Field

Several aspects of the present invention relates to a semiconductor device and a pixel electrode substrate that use an organic semiconductor material, an electro-optic device, an electronic apparatus, and a process for manufacturing the semiconductor device.

2. Related Art

The charge mobility of organic semiconductors is lower than that of single crystal silicon or polysilicon. For example, while single crystal silicon and polysilicon have charge mobilities of 1,350 cm²/Vs and several hundred cm²/Vs respectively, the charge mobility of organic semiconductors is at most several cm²/Vs. Accordingly, organic transistors using organic semiconductors exhibit low on-state current and on/off ratio. In view of the operation in a normal atmosphere, an organic transistor using an organic semiconductor having a relatively low ionization potential, such as pentacene or P3HT (polyhexylthiophene), is doped with oxygen or water in air to increase its carrier density. Consequently, its off-state current is undesirably increased and the on/off ratio is reduced accordingly.

In order to solve this problem, for example, a field-effect transistor disclosed in Japanese Unexamined Patent Application Publication No. 2005-166713 uses an organic semiconductor and has a dual gate structure to control the on/off ratio, drain current, threshold voltage, and other properties for high performance.

However, this transistor is structured by simply replacing the material of the semiconductor layer with an organic semiconductor material, and does not have cost superiority to silicon transistors.

### SUMMARY

An advantage of some aspect of the invention is that it provides an organic semiconductor transistor having a low off-sate current and a high on/off ratio at a relatively low cost.

According to an aspect of the invention, a transistor is provided which includes a first gate electrode, a second gate electrode formed over the first gate electrode, a source electrode formed above the first gate electrode, a drain electrode formed above the first gate electrode, and a semiconductor layer covering at least part of the source electrode and at least part of the drain electrode and disposed between the first gate electrode and the second gate electrode. The source electrode includes a first main portion and at least one first protrusion protruding in a direction intersecting the direction in which the first main portion extends. The drain electrode includes at least one second protrusion protruding toward the first main portion.

Such a structure leads to a transistor having a high on/off ratio.

Preferably, one of the first gate electrode and the second gate electrode has a lower resistance than the other gate electrode. Consequently, the total resistance of the gate electrodes can be low even if the other gate electrode is made of a relatively high-resistance material. If the other gate electrode has a low resistance, it can be used as part of a long wire extending on the substrate.

Preferably, the gate electrode having a lower resistance than the other gate electrode includes a metal film formed by vapor deposition or sputtering. Thus, the resulting gate electrode can have a low resistance.

Preferably, the first gate electrode and the second gate electrode are electrically connected to each other to form a double gate structure. By connecting the two electrodes at both ends of the semiconductor layer, the potential distribution can be uniformized.

According to another aspect of the invention, a pixel electrode substrate is provided which includes a base, a transistor, and a pixel electrode. The transistor includes a first gate electrode formed on the base, a second gate electrode formed over the first gate electrode, a source electrode formed above the first gate electrode, a drain electrode formed above the first gate electrode, and a semiconductor layer covering at least part of the source electrode and at least part of the drain electrode and disposed between the first gate electrode and the second gate electrode. The source electrode includes a first main portion and at least one first protrusion protruding in a direction intersecting the direction in which the main portion extends. The drain electrode has at least one second protrusion protruding from the pixel electrode toward the first main portion.

Such a structure leads to a pixel electrode substrate including a transistor having a high on/off ratio.

The pixel electrode substrate may further include a first gate line and a second gate line that are connected to each other. The first gate electrode is formed as part of the first gate line, and the second gate electrode is formed as part of the second gate line. Thus, wires of the substrate can be formed simultaneously with the formation of the electrodes of the transistor.

According to another aspect of the invention, an electro-optic device is provided which includes the above transistor or the above pixel electrode substrate.

According to another aspect of the invention, an electronic apparatus is provided which includes the transistor.

According to another aspect of the invention, a process for manufacturing a semiconductor element is provided. The process includes forming a first gate electrode on a base, forming a first gate insulating layer on the first gate electrode, forming a semiconductor layer over the first gate electrode, forming a second gate insulating layer on the semiconductor layer, and forming a second gate electrode on the second gate insulating layer. The second gate electrode is formed by a method different from the method for forming the first gate electrode.

Thus, a semiconductor element can be produced which has a double gate structure including a first and a second gate electrode made of different materials.

The formation of the first gate electrode may be performed by vapor deposition or sputtering of a metal. Thus, a low-resistance gate electrode can be formed.

Preferably, the second gate electrode is formed by printing. Printing can be preformed at relatively low temperatures and allows patterning without etching. Hence, the semiconductor layer is not affected by heat or etchant.

According to another aspect of the invention, a semiconductor device is provided which includes a substrate, a plurality of electrodes, an organic semiconductor layer between the electrodes, a first and a second gate electrode disposed at both sides of the organic semiconductor layer, and gate insulating layers disposed between the organic semiconductor layer and the first gate electrode and between the organic semiconductor layer and the second gate electrode. The first and second gate electrodes are connected to each other and at least one of these two gate electrodes is formed by a printing technique.

Since at least one of the first and the second gate electrode sandwiching the organic semiconductor layer is formed by a printing technique that can be performed at a relatively low temperature without etching, the degradation of the organic semiconductor layer by heat or etching can be prevented and the semiconductor device including an organic semiconductor transistor can be provided at a relatively low cost.

Preferably, the other gate electrode is formed by a method other than the printing technique and has a lower resistance than the gate electrode formed by the printing technique. Consequently, attenuation or delay of signals transmitted through the gate electrodes can be reduced.

Preferably, the other gate electrode is a metal layer formed by vapor deposition or sputtering. Thus, the resulting gate electrode has a low resistance.

Preferably, the semiconductor device further includes a gate line extending on the substrate and the other gate electrode is part of the gate line. If the semiconductor device is used as a pixel driving transistor of the pixel substrate of an active matrix display, a plurality of gate lines of the substrate, which define the pixel regions together with data lines on the substrate, can act as gate electrodes. In addition, by reducing the resistance of the gate electrode, the signal delay in the gate line can be reduced.

Preferably, the semiconductor layer and the gate insulating layer are formed by a printing technique. Since the printing technique can be performed avoiding etching and a high temperature step, degradation of the organic semiconductor layer can be prevented in the manufacturing process.

Preferably, the printing technique is performed by a liquid ejecting method. This method advantageously allows patterning with no contact with the substrate.

Such printing techniques include screen printing, flexography, offset lithography, an ink jet (liquid ejecting) method, and microcontact printing.

The semiconductor device can be used in electro-optic devices or electronic apparatuses, such as liquid crystal devices, organic EL devices, and electrophoretic display devices.

According to another aspect of the invention, a process for manufacturing a semiconductor device is provided. The process includes: forming a gate line extending in a direction on a substrate; forming a first gate insulating layer on the gate line in a region where an active element is to be formed; forming a plurality of electrodes on the first gate insulating layer; forming an organic semiconductor layer between the electrodes on the first gate insulating layer; forming a second gate insulating layer to cover the organic semiconductor layer; and forming a second gate electrode connected to the gate line along the gate line on the second gate insulating layer by a printing technique.

This process provides a transistor having a double gate structure, in which the organic semiconductor layer is disposed between two gate electrodes. By forming the second gate electrode overlying the organic semiconductor layer by a printing technique, an organic semiconductor transistor (semiconductor device) can be produced at relatively low cost while preventing the degradation of the organic semiconductor layer by heat or etching.

Preferably, the gate line is formed by vapor deposition or sputtering of a metal. Thus, a low-resistance gate line (gate electrode) can be formed.

Preferably, the organic semiconductor and the second gate insulating layer are formed by a printing technique. Thus, the degradation of the organic semiconductor layer by heat or etching can be prevented.

### BRIEF DESCRIPTION OF THE DRAWINGS

The invention will be described with reference to the accompanying drawings, wherein like numbers reference like elements.

FIGS. 1A to 1D are representations of a process for manufacturing organic semiconductor transistors according to a first embodiment.

FIGS. 2A to 2C are representations of a process for manufacturing the organic semiconductor transistors according to the first embodiment.

FIG. 3 is a plan view of the organic semiconductor transistors used as the driving transistors of pixel electrodes.

FIG. 4 is a fragmentary enlarged view of one of the organic semiconductor transistors shown in FIG. 3.

FIGS. 5A to 5D are representations of a process for manufacturing organic semiconductor transistors according to a second embodiment.

FIGS. 6A to 6C are representations of a process for manufacturing the organic semiconductor transistors according to the second embodiment.

FIG. 7 is a plan view of the organic semiconductor transistors used as the driving transistors of pixel electrodes.

FIG. 8 is a fragmentary enlarged view of one of the organic semiconductor transistors shown in FIG. 7.

FIGS. 9A to 9D are representations of electronic apparatuses using the organic semiconductor transistors according to an embodiment of the invention.

### DESCRIPTION OF EXEMPLARY EMBODIMENTS

Preferred embodiments of the invention will now be described with reference to the drawings.

### First Embodiment

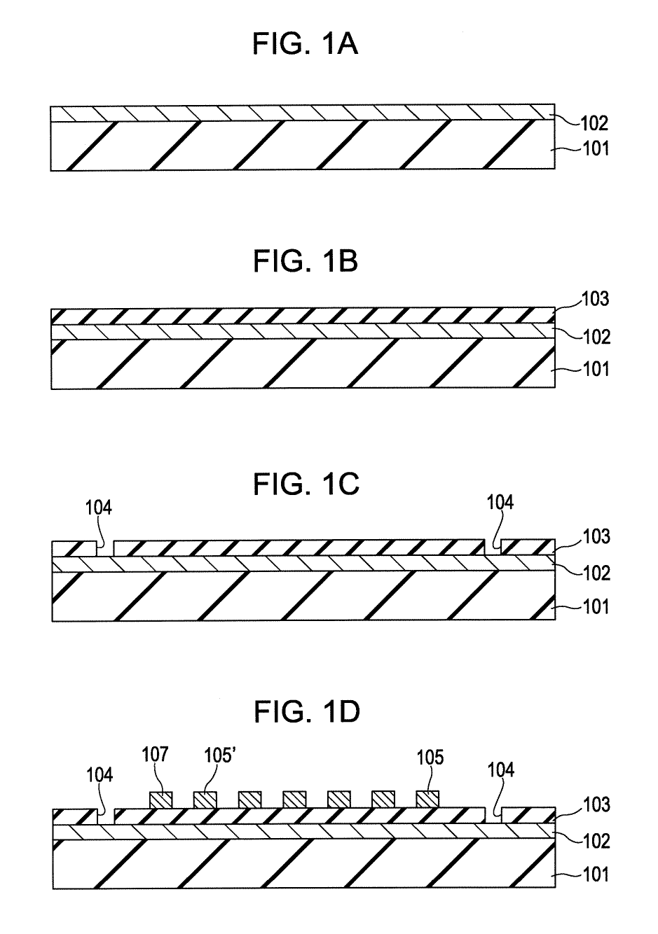

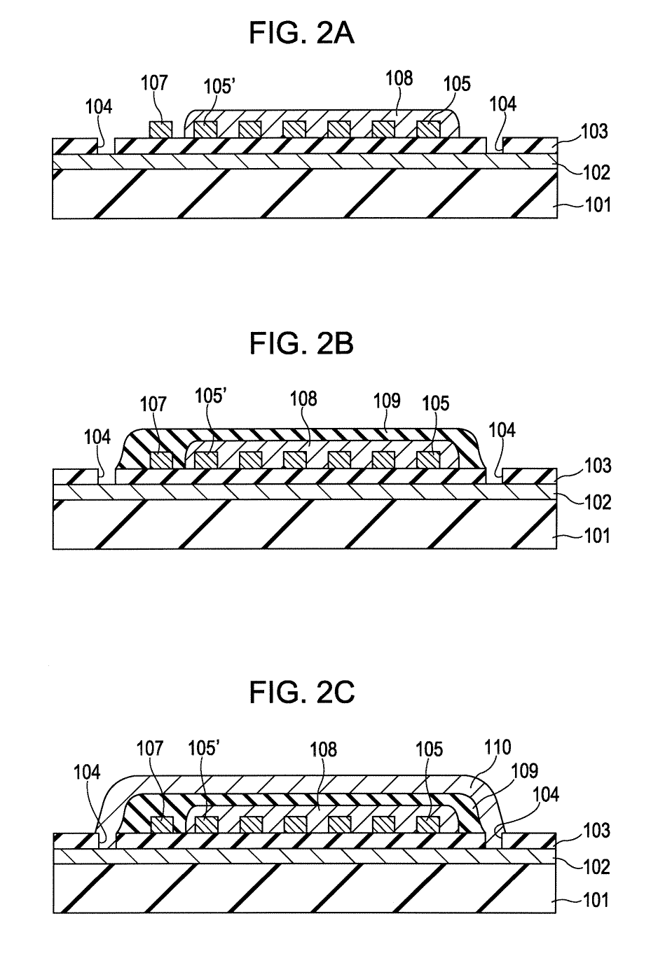

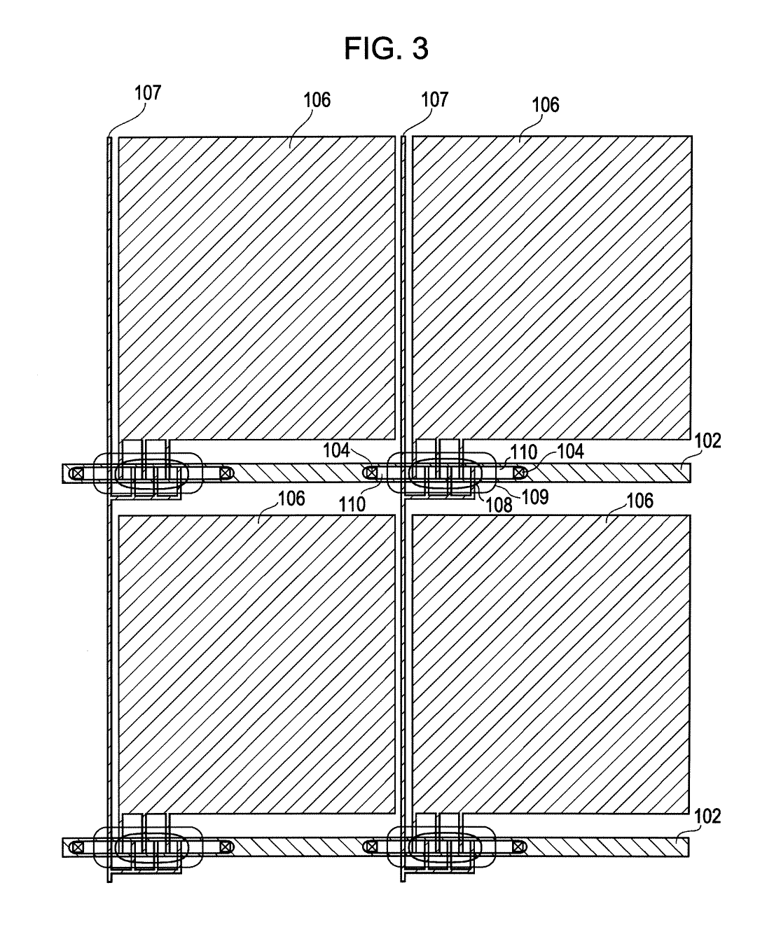

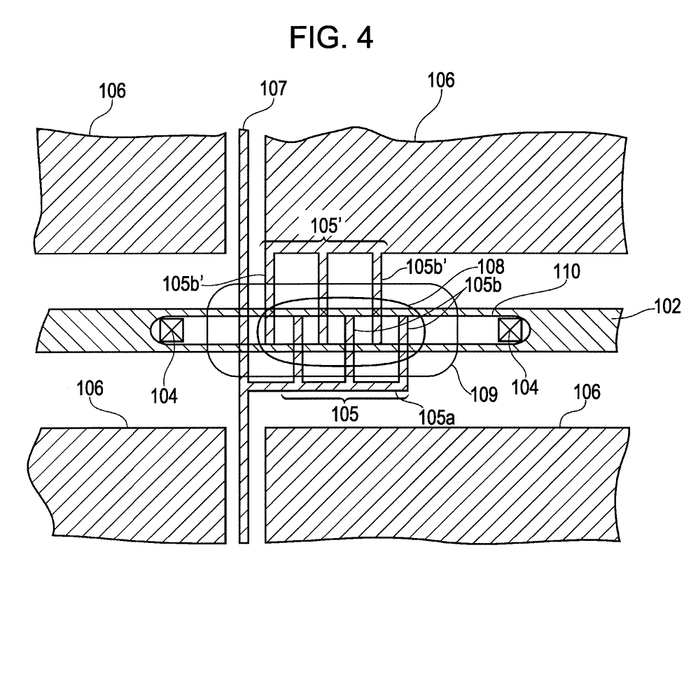

FIGS. 1A to 4 illustrate organic semiconductor transistors according to the present embodiment, used in a pixel driving circuit of a display device. FIGS. 1A to 2C are representations of a process for manufacturing the organic semiconductor transistors; FIG. 3 is a plan view of the pixel driving circuit; and FIG. 4 is a fragmentary enlarged view of one of the organic semiconductor transistors shown in FIG. 3

First, gate lines 102 are formed on an insulating substrate 101, as shown in FIG. 1A. The insulating substrate 101 can be made of, for example, a plastic, such as PET (polyethylene terephthalate), or glass. Other materials may also be used for the substrate, including plastics (resins) such as polyethylene naphthalate (PEN), polyether sulfone (PES), polycarbonate (PC), aromatic polyester (liquid crystal polymer), and polyimide (PI). Any other material, such as glass, silicon, metal, or gallium arsenide may also be used as long as it is flexible.

The first gate lines 102 can be formed by depositing a metal, such as aluminum, nickel, copper, titanium, silver, gold, or platinum, by vapor-deposition or sputtering and then patterning the metal layer by photolithography. Alternatively, a liquid containing metal particles may be ejected (or applied) by a printing technique represented by an ink jet (liquid ejecting) method, followed by drying. If metal particles are used, heat treatment may be performed to increase the electrical contact among the metal particles after applying the liquid and removing the solvent. The heat treatment is performed generally in a normal atmosphere, but may be performed in an atmosphere of an inert gas, such as nitrogen, argon, or helium, if necessary. Exemplary types of metal particles include silver, aluminum and gold.

As an alternative to the ink jet method, the gate lines 102 may be formed by another printing technique, such as screen printing, flexography, offset lithography, liquid ejecting, or microcontact printing, according to the materials of the insulating substrate 101 and gate lines 102 and other factors.

Turning to FIG. 1B, a first gate insulating layer 103 is formed of acrylic resin, epoxy resin, or ester resin over each first gate line 102 by spin coating, dipping, or any other coating technique. If the first gate insulating layer 103 is patterned, it may be formed by a patterning technique, such as an ink jet method or photolithography.

Turning to FIG. 1C, contact holes 104 are formed in the gate insulating layer 103. In order to form the contact holes 104, for example, a photoresist applied over the gate insulating layer 103 is exposed through a mask for the contact holes and developed to form a resist mask, and the gate insulating layer 103 is etched through the resist mask (photolithography).

If the gate insulating layer 103 is formed of a photosensitive polymer (photoresist), small contact holes 104 can be formed in gate insulating layer 103 by directly exposing the photosensitive polymer through a mask for contact holes and developing the polymer. If the gate insulating layer 103 is formed of a resin, a solvent that can dissolve the resin may be ejected (or applied) onto desired positions by an ink jet method or the like so that part of the gate insulating layer 103 is removed to form the contact holes 104 in the gate insulating layer 103. Thus, the contact holes can be easily formed.

The contact holes 104 are provided so that the first gate line 102 can be connected to a second gate line 110 (described later) through two contact holes for each transistor.

one of the two contact holes 104 is provided so that a data line 107 can be located between this contact hole and a later-described source electrode 105. The other contact hole 104 is provided so that the source electrode 105 can be located between this contact hole and the data line 107.

Turning to FIG. 1D, a source electrode 105 and a drain electrode 105′, a pixel electrode 106, the data line 107, and so forth (see FIG. 4, described later) are formed on the gate insulating layer 103 in the same manner as the first gate line 102. The source and drain of a transistor in a strict sense are defined depending on the conductivity type of the semiconductor of the transistor and potentials. For the sake of convenience, in the present embodiment, the electrode connected to the data line 107 is defined as the source electrode 105, and the electrode connected to the pixel electrode 106 is defined as the drain electrode 105′.

The resulting substrate was subjected to oxygen plasma treatment and cleaning. Then, a liquid containing F8T2 (polyfluorene-thiophene copolymer) is applied by an ink jet method, followed by removing the solvent or other volatile components. Thus, a semiconductor layer 108 is formed to cover at least the source electrode 105 and the drain electrode 105′, as shown in FIG. 2A. In the present embodiment, the thickness of the semiconductor layer 108 is about 50 nm.

Any organic semiconductor material can be used for forming the semiconductor layer 108 by the ink jet method, as long as the material can be dispersed or dissolved in a solvent. Exemplary organic semiconductor materials include poly(3-alkylthiophene) such as (poly(3-hexylthiophene)(P3HT) and poly(3-octylthiophene), poly(2,5-thienylene vinylene)(PTV), poly(para-phenylene vinylene)(PPV), poly(9,9-dioctylfluorene-co-bis-N,N′-(4-methoxyphenyl)-bis-N,N′-phenyl-1,4-phenylenediamine)(PFMO), poly(9,9-sioctylfluorene-co-benzothiadiazole)(BT), fluorene-triallylamine copolymer, triallylamine polymer, fluorene-bithiophene copolymer, and other polymers.

In addition, low-molecular-weight organic semiconductor materials may be used for the ink jet method. Such materials include C60; metal phthalocyanines and their derivatives; acenes such as anthracene, tetracene, pentacene, and hexacene; and α-oligothiophenes such as quarterthiophene (4T), sexithiophene (6T), octithiophene (8T), dihexylquarterthiophene (DH4T), and dihexylsexithiophene (DH6T).

Since these low-molecular-weight organic semiconductor materials have a plurality of aromatic rings, they generally have rigid and hard molecular structures and accordingly have low solubilities. In order to increase the solubility, a long-chain alkyl substituent or the like may be introduced to the skeleton of the molecule by a synthetic chemical technique.

If vapor deposition, such as mask deposition, is used instead of the ink jet method, the above-listed low-molecular-weight semiconductor materials can be used because the solubility in a solvent is not important.

Turning now to FIG. 2B, a second gate insulating layer 109 is formed to cover the semiconductor layer 108. The second gate insulating layer 109 may be formed in the same manner as the first gate insulating layer 103.

If the second gate insulating layer 109 is formed by an ink jet method, it is desired that an appropriate solvent be selected for the liquid of the second gate insulating layer material so that the semiconductor layer 108 can be prevented from being dissolved as much as possible.

Turning to FIG. 2C, a second gate line 110 is formed on the second gate insulating layer 109 so as to cover the semiconductor layer 108 and the data line 107. The second gate line 110 comes in contact with the first gate line 102 through the contact holes 104.

Thus, a scanning signal transmitted through the first gate line 102 can be transmitted to the second gate line 110, so that the electrical continuity between the source electrode 105 and drain electrode 105′ in the semiconductor layer 108 can be controlled by the first gate line 102 and the second gate line 110. Thus, part of the first gate line 102 and at least part of the second gate line 110 function together as the gate electrode of a transistor.

The second gate line 110 can be formed by ejecting or applying, for example, a suspension of metal particles or an electroconductive polymer such as PEDOT (polyethylenedioxythiophene) by an ink jet method or other printing technique and then annealing or drying the formed layer. The first gate line 102 and the second gate line 110 constitute a double gate structure with the semiconductor layer 108 therebetween.

The resulting substrate thus prepared is covered with a protective layer or the like (no shown) and is used as the pixel electrode substrate (active matrix substrate) of an electro-optic device, such as a liquid crystal device or an electrophoretic device.

FIG. 3 is a plan view of the pixel electrode substrate prepared through the steps up to FIG. 2C. FIG. 4 is a fragmentary enlarged view of one of the organic semiconductor transistors acting as pixel-driving transistors.

As shown in these two figures, the first gate lines 102 and the data lines 107 intersect each other, and pixel electrodes 106 are disposed in regions defined by the first gate lines 102 and the data lines 107. A driving transistor for driving the pixel is disposed each intersection of the first gate lines 102 and the data lines 107. Each data line 107 is connected to the corresponding source electrodes, and each pixel electrode 106 is connected to the corresponding drain electrode 105′.

As shown in FIG. 4, the source electrode 105 is connected to the data line 107 and includes a main portion 105a extending in the direction intersecting the data line 107 and a plurality of first protrusions 105b protruding from the main portion 105a in the direction intersecting the direction in which the main portion 105a extends.

The drain electrode 105′ includes a plurality of second protrusions 105b′ protruding from the pixel electrode 106. The first protrusions 105b protrude from the main portion 105a of the source electrode 105 toward the pixel electrode 106. The second protrusions 105b′ protrude from the pixel electrode 106 toward the main portion 105a.

The first and the second protrusions 105b and 105b′ are arranged in such a manner that each one of the second protrusions 105b′ is located between any two adjacent first-protrusions 105b; hence, the source electrode 105 and the drain electrode 105′ are each formed in a comb teeth shape.

The second protrusion 105b′ located closest to the data line 107 is disposed between the data line 107 and the first protrusion 105b closest to the data line 107.

Since the transistor according to the present embodiment includes a comb teeth-like source electrode 105 and drain electrode 105′ as described above, large part of them can function as the channels of the semiconductor layer 108. Accordingly, even if the semiconductor layer 108 has a low mobility, a relatively high current can be allowed to flow between the source electrode 105 and the drain electrode 105′.

In the above-described embodiment, the semiconductor layer 108 is disposed between the first gate line 102 and the second gate line 110, being layered in the thickness direction of the semiconductor layer 108, and the depletion layer of the semiconductor layer 108 can be controlled with gate current from the upper and lower gate lines. Thus, the depletion layer in the off state expands to reduce the off-state current. The gate lines disposed over and under the semiconductor layer 108 expand the channel region through which carriers pass, in the thickness direction of the semiconductor layer 108, thereby increasing the on-state current.

The first gate line 102 and the second gate line 110 may have different resistances. For example, the first gate line 102 is formed so as to have a low resistance by sputtering or vapor deposition, and the second gate line 110 is formed so as to have a higher resistance than the first gate line 102 by an ink jet method using a suspension of metal particles.

By forming the second gate line 110 by an ink jet method, the damage to the second gate insulating layer 109 or the semiconductor layer 108 in the step of forming the second gate line 110 can be prevented more than by deposition, such as vapor deposition or sputtering.

### Second Embodiment

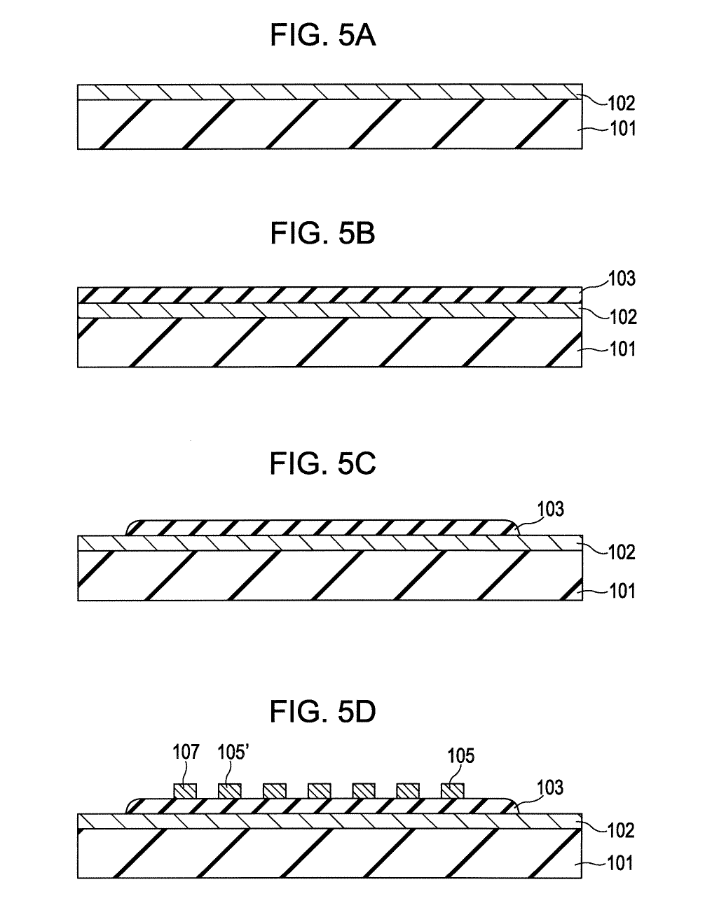

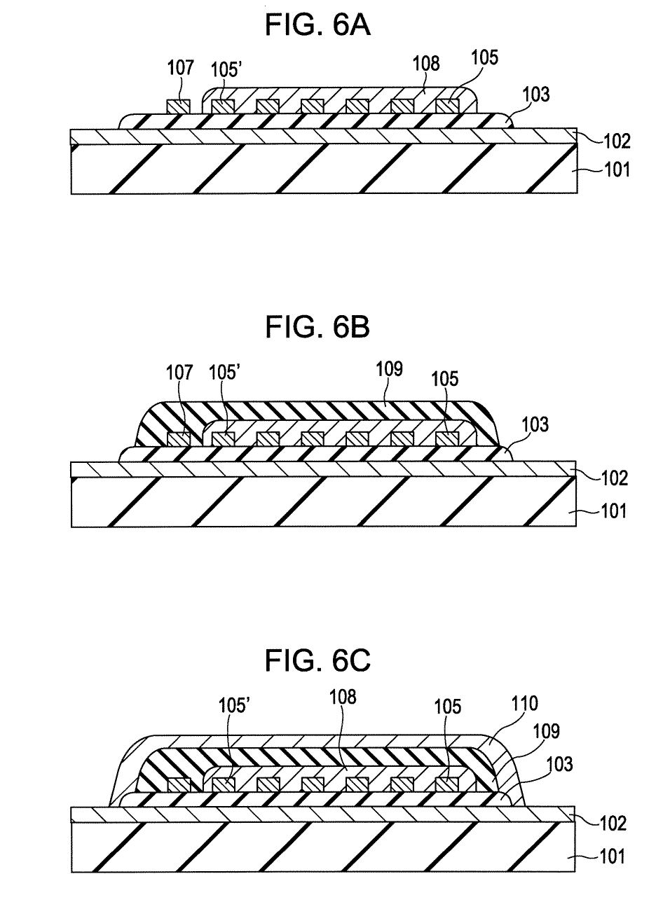

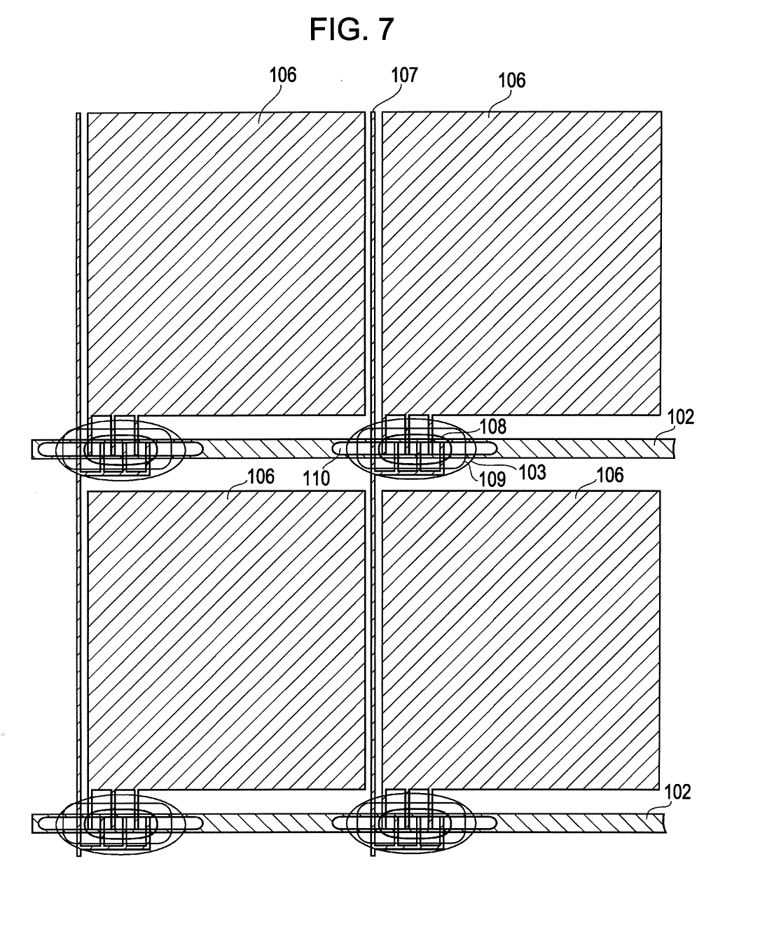

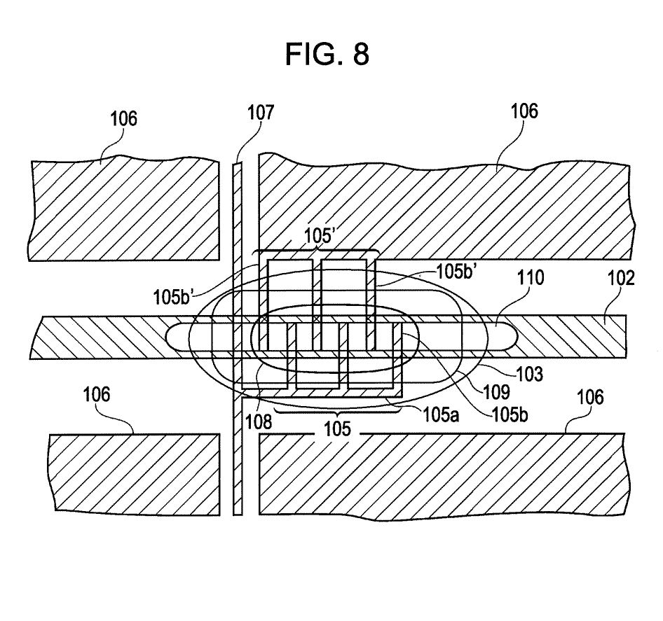

FIGS. 5A to 8 illustrate organic semiconductor transistors according to a second embodiment, used in another pixel driving circuit of an electro-optic device. FIGS. 5A to 6C are representations a process for manufacturing the organic semiconductor transistors; FIG. 7 is a plan view of the pixel driving circuit; and FIG. 8 is a fragmentary enlarged view of one of the organic semiconductor transistors shown in FIG. 7. The parts in these figures corresponding to those in FIGS. 1A to 4 are designated by the same numerals.

First, first gate lines 102 are formed on an insulating substrate 101, as shown in FIG. 5A in the same manner as in the first embodiment. The insulting substrate 101 can be, for example, made of a plastic, such as PET (polyethylene terephthalate), or glass. The first gate lines 102 can be formed by depositing a metal, such as aluminum, nickel, copper, titanium, silver, gold, or platinum, by vapor deposition or sputtering and then patterned the metal payer by photolithography. Alternatively, a liquid containing metal particles may be ejected (or applied) by a printing technique represented by an ink jet method, followed by drying. Exemplary types of metal particles include silver, aluminum and gold.

Turning to FIG. 5B, a first gate insulating layer 103 is formed of acrylic resin, epoxy resin, or ester resin over each first gate line 102 by spin coating, dipping, or a printing technique such as an ink jet method.

Turning to FIG. 5C, regions (island regions) of the gate insulating layer 103 on the substrate corresponding to the regions intended for organic semiconductor transistors are left and the other regions are removed to expose the gate lines 102. In order to form such island regions, for example, a photoresist applied over the gate insulating layer 103 is exposed through a mask and developed to form a resist mask, and the gate insulating layer 103 is etched through the resist mask (photolithography).

If the gate insulating layer 103 is formed of a photosensitive polymer (photoresist), the islands of the gate insulating layer may be formed by directly exposing the photosensitive polymer through a mask for forming the islands and developing the polymer. If the gate insulating layer 103 is formed of a resin, a solvent that can dissolve the resin may be ejected (or applied) onto desired positions by an ink jet method or the like to form the islands of the gate insulating layer 103.

Turning to FIG. 5D, pairs of a source electrode 105 and a drain electrode 105′, a plurality of pixel electrodes 106, a plurality of data lines 107 and so forth (see FIG. 8, described later) are formed on the islands of the gate insulating layer 103 in the same manner as the first gate lines 102. As described above, the source and drain of a transistor in a strict sense are defined depending on the conductivity type of the semiconductor layer of the transistor and potentials. For the sake of convenience, in the present embodiment, the electrode connected to the data line 107 is defined as the source electrode 105, and the electrode connected to the pixel electrode 106 is defined as the drain electrode 105′. The source electrode 105 and the drain electrode 105′ are each formed in a comb teeth shape.

Subsequently, the resulting substrate is subjected to oxygen plasma treatment and cleaning. Then, F8T2 (polyfluorene-thiophene copolymer) being an organic semiconductor is dripped onto the substrate by an ink jet method, followed by removing the solvent or other volatile components from the liquid. Thus, a semiconductor layer 108 is formed to cover at least the source electrode 105 and the drain electrode 105′, as shown in FIG. 6A. In the present embodiment, the thickness of the semiconductor layer 108 is about 50 nm. The material of the organic semiconductor layer can be selected from the above listed polymer and low-molecular-weight organic semiconductors.

Turning to FIG. 6B, a second gate insulating layer 109 is formed to cover the organic semiconductor layer 108 and the data line 107. The second gate insulating layer 109 may be formed in the same manner as the first gate insulating layer 103. In the present embodiment, the second gate insulating layer is preferably formed by a printing technique (patterning), such as an ink jet method or transfer printing, because the second gate insulating layer must be provided only the desired region and must not affect the organic semiconductor layer 108.

Turning to FIG. 6C, a second gate line 110 is formed on the second gate insulating layer 109 so as to cover the semiconductor layer 108 and the data line 107. Both ends of the second gate line 110 come in contact with the first gate line 102 exposed at both outer regions of the gate insulating layer 109.

Consequently, a scanning signal transmitted through the first gate line 102 is transmitted to the second gate line 110, and the continuity between the source electrode 105 and the drain electrode 105′ in the semiconductor layer 108 is controlled by the first and second gate lines 102 and 110. Thus, part of the first gate line 102 and at least part of the second gate line 110 function together as the gate electrode of a transistor.

The second gate line 110 can be formed by ejecting or applying, for example, a metal particle suspension or a conductive polymer, such as PEDOT (polyethylenedioxythiophene), by a printing technique, such as an ink jet method or transfer printing, and then annealing or drying the formed layer. The first gate line 102 and the second gate line 110 sandwich the organic semiconductor layer from both sides in the vertical direction to form a type of double gate structure.

The resulting pixel electrode substrate thus prepared is further provided with a protective layer and other layers (not shown) as required, and is thus used as a pixel electrode substrate (active matrix substrate) of an electro-optic device, such as a liquid crystal device or an electrophoretic display device.

FIG. 7 is a plan view of the pixel electrode substrate of a display prepared through the steps up to FIG. 6C. FIG. 8 is a fragmentary enlarged view of one of the organic semiconductor transistors acting as pixel-driving transistors.

As shown in these two figures, the first gate lines 102 and the data lines 107 intersect each other, and pixel electrodes 106 are disposed in regions defined by the first gate lines 102 and the data lines 107. A driving transistor for driving the pixel is disposed each intersection of the first gate lines 102 and the data lines 107. Each data line 107 is connected to the corresponding source electrodes, and each pixel electrode 106 is connected to the corresponding drain electrode 105′.

As shown in FIG. 8, the source electrode 105 is connected to the data line 107 and includes a main portion 105a extending in the direction intersecting the data line 107 and a plurality of first protrusions 105b protruding from the main portion 105a in the direction intersecting the direction in which the main portion 105a extends.

The drain electrode 105′ includes a plurality of second protrusions 105b′ protruding from the pixel electrode 106. The first protrusions 105b protrude from the main portion 105a of the source electrode 105 toward the pixel electrode 106. The second protrusions 105b′ protrude from the pixel electrode 106 toward the main portion 105a.

The first and the second protrusions 105b and 105b′ are arranged in such a manner that each one of the second protrusions 105b′ is located between any two adjacent first protrusions 105b; hence, the source electrode 105 and the drain electrode 105′ are each formed in a comb teeth shape.

The second protrusion 105b′ located closest to the data line 107 is disposed between the data line 107 and the first protrusion 105b closest to the data line 107.

Since the transistor according to the present embodiment includes a comb teeth-like source electrode 105 and drain electrode 105′ as described above, large part of them can function as the channels of the semiconductor layer 108. Accordingly, even if the semiconductor layer 108 has a low mobility, a relatively high current can be allowed to flow between the source electrode 105 and the drain electrode 105′.

In the above-described embodiment, the semiconductor layer 108 is disposed between the first gate line 102 and the second gate line 110, being layered in the thickness direction of the semiconductor layer 108, and the depletion layer of the semiconductor layer 108 can be controlled with gate current from both the upper and lower gate lines. Thus, the depletion layer in the off state expands to reduce the off-state current. The gate lines disposed over and under the semiconductor layer 108 expand the channel-region through which carriers pass, in the thickness direction of the semiconductor layer 108, thereby increasing the on-state current.

Since in the present embodiment, the second gate insulating layer and the second gate line are formed by a printing technique represented by an ink jet method, the transistor can be produced at a low cost without damage to the organic semiconductor layer.

The first gate line 102 and the second gate line 110 may have different resistance as well. For example, the first gate line 102 is formed so as to have a low resistance by sputtering or vapor deposition, and the second gate line 110 is formed so as to have a higher resistance than the first gate line 102 by an ink jet method using a suspension of metal particles.

By forming the second gate line 110 by an ink jet method, the damage to the gate insulating layer 109 or the semiconductor layer 108 can be prevented more than by deposition, such as vapor deposition or sputtering, in the step of forming the second gate line 110.

Alternatively, the lower gate line (gate electrode) of the double gate structure may be formed by sputtering or vapor deposition that can form a low-resistance metal layer, or by an ink jet method combined with annealing at an appropriate temperature (relatively high temperature), and the upper gate line (gate electrode) of the double gate structure may be formed of a metal by an ink jet method combined with annealing at a limited temperature (relatively low temperature) or drying.

Consequently, the delay or attenuation of signals from gate lines extending on the substrate can be prevented, and the degradation of the organic semiconductor layer by heat or etching can be prevented.

In the above-described embodiments, the organic semiconductor layer 108 and the source and drain electrodes 105 and 105′ may be formed in inverse order. In this instance, the source and drain electrodes 105 and 105′ must be formed without negatively affecting the organic semiconductor layer 108. Accordingly, it is preferable that a printing technique represented by an ink jet method be applied.

In the above embodiments, the organic semiconductor layer is controlled with gate current from both the upper and lower gate lines, and thus the depletion layer in the off state expands to reduce the off-state current, as described above. In addition, channels are formed at two points, consequently increasing the on-state current. Accordingly, the on/off ratio is increased.

Furthermore, by forming the gate insulating layers, the gate lines, and the data lines by a printing technique represented by an ink jet method, an organic semiconductor TFT circuit can be produced at a low cost.

### Electronic Apparatus

An electronic apparatus including the organic semiconductor TFTs prepared in the above-described process will now be described. The organic semiconductor TFTs prepared according to the above-describe embodiments can be used for circuits or displays of a variety of electronic apparatuses, such as liquid crystal display panels, electroluminescent display panels, and electrophoretic display panels.

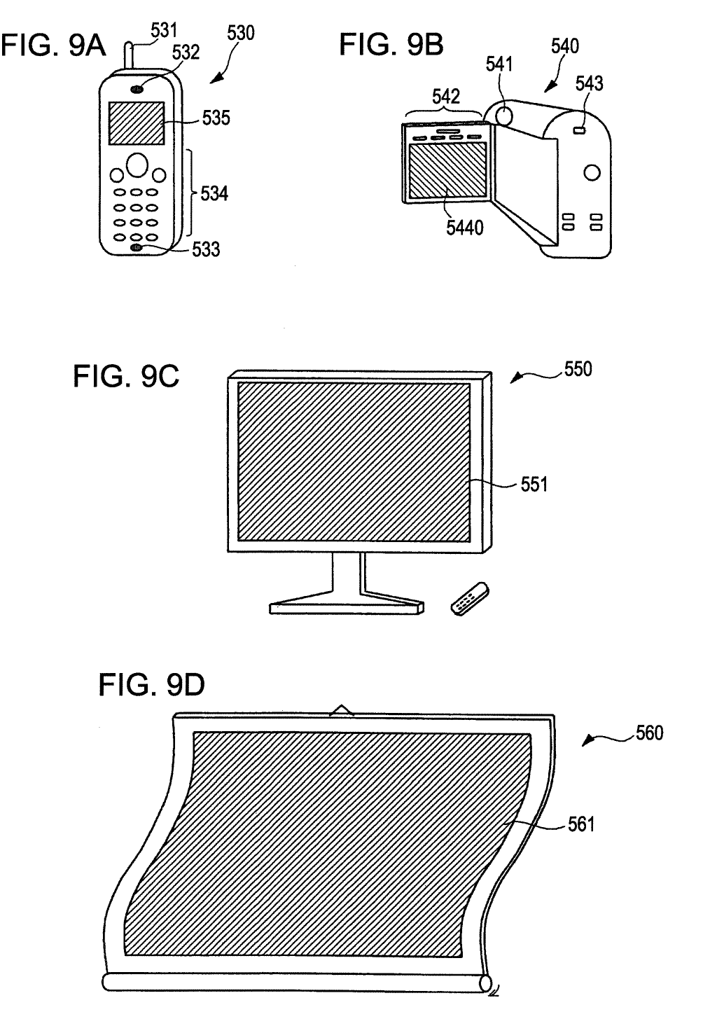

FIGS. 9A to 9D are perspective views of such electronic apparatuses. FIG. 9A shows a cellular phone 530 including an antenna portion 531, an audio output portion 532, an audio input portion 533, a controlling portion 534, and a display 535.

FIG. 9B shows a video camera 540 including an image receiving portion 541, a controlling portion 542, audio input portion 543, and a display 544.

FIG. 9C shows a TV apparatus 550 including a display 551.

FIG. 9D shows a roll-up TV apparatus 560 including a display 561. The organic TFT according to an embodiment of the invention can be used in a variety of electronic apparatuses without being limited to those apparatuses. For example, the organic TFT can also be used in fax machines having a display function, digital camera finders, portable TV sets, electronic notebooks, electronic billboards, advertising displays, and so forth.

While the invention has been described using preferred embodiments, it will be appreciated by those skilled in the art that various modifications in form and detail may be made without departing from the scope and spirit of the invention.

What is claimed is:

1. A transistor comprising:
a first gate electrode;
a second gate electrode formed over the first gate electrode;
a source electrode formed above the first gate electrode, the source electrode including a first main portion extending in a direction and at least one first protrusion protruding in a direction intersecting the direction in which the first main portion extends;
a drain electrode formed above the first gate electrode, the drain electrode including at least one second protrusion protruding toward the first main portion; and
a semiconductor layer covering at least part of the source electrode and at least part of the drain electrode and disposed between the first gate electrode and the second gate electrode.

2. The transistor according to claim 1, wherein one of the first gate electrode and the second gate electrode has a lower resistance than the other gate electrode.

3. The transistor according to claim 2, wherein the gate electrode having a lower resistance than the other gate electrode includes a metal film formed by vapor deposition or sputtering.

4. The transistor according to claim 1, wherein the first gate electrode and the second gate electrode are electrically connected to each other.

5. A pixel electrode substrate comprising:
a base;
a pixel electrode; and
a transistor including a first gate electrode formed on the base, a second gate electrode formed over the first gate electrode, a source electrode formed above the first gate electrode and including a first main portion extending in a direction and at least one first protrusion protruding in a direction intersecting the direction in which the first main portion extends, a drain electrode formed above the first gate electrode and including at least one second protrusion protruding from the pixel electrode toward the first main portion, and a semiconductor layer covering at least part of the source electrode and at least part of the drain electrode and disposed between the first gate electrode and the second gate electrode.

6. The pixel electrode substrate according to claim 5, further comprising a first gate line and a second gate line that are electrically connected to each other, wherein the first gate electrode is part of the first gate line, and the second gate electrode is part of the second gate line.

7. An electro-optic device comprising the transistor as set forth in claim 1 or the pixel electrode substrate as set forth in claim 5.

8. An electronic apparatus comprising the transistor as set forth in claim 1.

9. A process for manufacturing a semiconductor element, comprising:
forming a first gate electrode on a base by a method;
forming a first gate insulating layer on the first gate electrode;
forming a semiconductor layer over the first gate electrode;
forming a second gate insulating layer on the semiconductor layer; and
forming a second gate electrode on the second gate insulating layer by a method different from the method for forming the first gate electrode.

10. The process according to claim 9, wherein the method for forming the first gate electrode is performed by vapor deposition or sputtering of a metal.

11. The process according to claim 9, wherein the method for forming the second gate electrode is performed by printing.
